(19) United States
(12) Patent Application Publication
(10) Pub. No.: US 2024/0187022 A1
(43) Pub. Date: Jun. 6, 2024

(54) SEMICONDUCTOR DEVICE, COMMUNICATION DEVICE, AND METHOD OF SETTING LOCAL OSCILLATOR FREQUENCY

(71) Applicant: Samsung Electronics Co., Ltd., Suwon-si (KR)

(72) Inventors: Kiho KIL, Suwon-si (KR); Anna KIM, Suwon-si (KR); Wonseok JEONG, Suwon-si (KR); Ilmuk CHOI, Suwon-si (KR)

(73) Assignee: Samsung Electronics Co., Ltd., Suwon-si (KR)

(21) Appl. No.: 18/529,377

(22) Filed: Dec. 5, 2023

(30) Foreign Application Priority Data
Dec. 6, 2022 (KR) 10-2022-0168614

(51) Int. Cl. H04B 1/00; H04B 1/04

(52) U.S. Cl. CPC H04B 1/0053; H04B 1/04

(57) ABSTRACT

A semiconductor device including processing circuitry configured to determine a carrier band and reference signal bands based on a data signal received from a network, the carrier band and reference signal bands being allocated by the network, the reference signal bands corresponding to a reference signal for channel estimation, and the reference signal being within a carrier band, and output a control signal causing a local oscillator (LO) to change a LO frequency to a value that does not overlap the reference signal bands.

### CROSS-REFERENCE TO RELATED APPLICATION

This application claims the priority and benefit of Korean Patent Application No. 10-2022-0168614, filed on Dec. 6, 2022, with the Korean Intellectual Property Office, the entire contents of which are incorporated herein by reference.

### BACKGROUND

### 1. Field

The inventive concepts relate to a semiconductor device, a communication device, and a method of setting a local oscillator frequency.

### 2. Description of Related Art

Unmodulated audio has a frequency of several kHz, and unmodulated video or data has a frequency of several to several tens of MHz. A frequency domain having unmodulated information is referred to as baseband. Since crosstalk may occur when communication devices exchange information in the same frequency band (or similar frequency bands), a method of converting baseband signals into carrier signals having different frequency bands and transmitting/receiving the same is used.

A frequency mixer is used to convert a baseband signal into a carrier signal. When a local oscillator (LO) signal is applied to the mixer, a carrier signal having a shifted center frequency may be generated while including baseband signal information. When a carrier band and a frequency of the LO signal overlap, the LO signal may affect the carrier signal.

### SUMMARY

An aspect of the inventive concepts is to provide a method of setting an LO frequency capable of minimizing (or reducing) an adverse effect of an LO signal on a carrier signal within a predetermined (or alternatively, given) radio frequency (RF) signal band, a semiconductor device, and a communication device.

An aspect of the inventive concepts is to provide a method of setting an LO frequency capable of improving channel estimation performance of a network, and reception performance of a communication device, a semiconductor device, and a communication device.

According to an aspect of the inventive concepts, a semiconductor device including processing circuitry configured to determine a carrier band and reference signal bands based on a data signal received from a network, the carrier band and reference signal bands being allocated by the network, the reference signal bands corresponding to a reference signal for channel estimation, and the reference signal being within a carrier band, and output a control signal causing a local oscillator (LO) to change a LO frequency to a value that does not overlap the reference signal bands.

According to an aspect of the inventive concepts, a communication device including processing circuitry, a radio frequency (RF) circuit configured to convert a baseband signal into a carrier signal, the carrier signal including a plurality of subcarrier signals, and an antenna module configured to transmit the carrier signal to a network, wherein the RF circuit is configured to generate a local oscillator (LO) signal having an LO frequency, generate a first signal in which a difference between a target center frequency of the carrier signal and the LO frequency is compensated when the baseband signal is input, and output the carrier signal having the target center frequency by mixing the first signal and the LO signal, and the processing circuitry is configured to control the LO frequency to avoid (e.g., at least partially avoid) reference signal bands among subcarrier bands included in a carrier band, the reference signal bands being allocated for transmitting a reference signal for channel estimation, and the carrier band being allocated by the network.

According to an aspect of the inventive concepts, a method of setting a local oscillator (LO) frequency of an LO signal, the LO signal being for converting a baseband signal into a carrier signal, the method includes setting a radio frequency (RF) band of a band pass filter for passing the carrier signal, determining a carrier band and a reference signal band, the reference signal band being allocated to a reference signal for channel estimation from among a plurality of subcarrier bands included in the carrier band, and controlling the LO frequency to have a value that does not overlap the reference signal band in response to an RF bandwidth of the RF band being less than or equal to a threshold value, a difference between the LO frequency and a target center frequency of the carrier band being compensated.

### BRIEF DESCRIPTION OF DRAWINGS

The above and other aspects, features, and advantages of the inventive concepts will be more clearly understood from the following detailed description taken in conjunction with the accompanying drawings, in which:

FIG. 1 is a diagram illustrating a wireless communication system according to example embodiments of the inventive concepts;

FIG. 2 is a diagram illustrating an example in which a baseband signal is upwardly converted into a carrier signal;

FIGS. 3A to 3C are diagrams for illustrating a communication device in detail according to example embodiments of the inventive concepts;

FIG. 4 is a diagram illustrating a first example of a relationship between an RF signal band and an LO frequency;

FIG. 5 is a diagram illustrating a resource block in a wireless communication system communicating in an OFDM scheme;

FIG. 6 is a diagram illustrating a second example of a relationship between an RF signal band and an LO frequency;

FIG. 7 is a diagram illustrating a method for setting an LO frequency according to example embodiments of the inventive concepts;

FIGS. 8 to 9B are diagrams specifically illustrating a method of setting an LO frequency according to example embodiments of the inventive concepts; and

FIG. 10 is a diagram illustrating an operating method of a communication system according to example embodiments of the inventive concepts.

### DETAILED DESCRIPTION

Hereinafter, example embodiments of the inventive concepts will be described with reference to the accompanying drawings as follows.

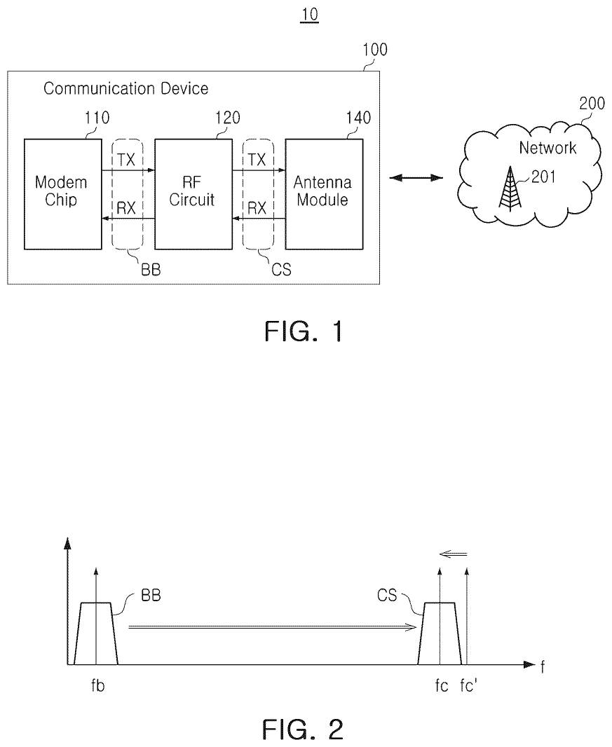

FIG. 1 is a diagram illustrating a wireless communication system according to example embodiments of the inventive concepts.

The wireless communication system 10 may include a communication device 100 and a network 200. The communication device 100 may be fixed or mobile, and may refer to any device capable of transmitting and receiving data and control information through wireless communication with the network 200. For example, the communication device 100 includes (e.g., may be) a terminal, a terminal equipment, a terminal device, a mobile station (MS), a mobile terminal (MT), a user terminal (UT), a subscribe station (SS), a wireless device, a handheld device, and the like.

The network 200 may include a base station 201. The base station 201 may refer to a fixed station communicating with the communication device 100 or another base station. The base station 201 may exchange data and control information by communicating with the communication device 100 or another base station. For example, the base station 201 may also be referred to as a Node B, an evolved Node B (eNB), a next generation Node B (gNB), a sector, a site, a base transceiver system (BTS), an access point (AP), a relay node, a remote radio head (RRH), a radio unit (RU), a small cell, and the like. The base station 201 may be interpreted as comprehensively representing some regions or functions covered by a base station controller (BSC) in code-division multiple access (CDMA), a Node-B in wideband CDMA (WCDMA), an eNB in long-term evolution (LTE), a gNB or a sector (site) in fifth generation (5G) new radio (NR), and may cover various coverage regions such as megacells, macrocells, microcells, picocells, femtocells, relay nodes, RRHs, RUs, small cell communication ranges, and the like. According to example embodiments, operations described herein as being performed by the network 200 may be performed by the base station 201 and/or another device within (e.g., connected to, controlling the operations of, etc.) the network 200.

The communication device 100 may access a network 200 through the base station 201. The communication device 100 may communicate with the network 200 according to any radio access technology (RAT). For example, as a non-limiting example, the communication device 100 may communicate according to a 5th Generation (5G) system, a 5G New Radio (NR) system, a Long Term Evolution (LTE) system, a Code Division Multiple Access (CDMA) system, a GSM (Global System for Mobile Communications) system, a Wireless Local Area Network (WLAN) system, or any other RAT.

The communication device 100 may include a modem chip 110, a radio frequency (RF) circuit 120, and/or an antenna module 140. The communication device 100 may provide a transmission path for outputting a transmission signal TX to the base station 201 and a reception path for receiving a reception signal RX from the base station 201.

The modem chip 110 may generate a baseband signal BB based on data to be transmitted to the base station 201 and provide the same to the RF circuit 120 or extract data from the baseband signal BB received from the RF circuit 120. For example, the modem chip 110 may include at least one digital-to-analog converter (DAC) converting modulated digital data from data to be transmitted to the base station 201 to output a baseband signal BB. The modem chip 110 may further include at least one analog-to-digital converter (ADC), and the at least one ADC may convert a baseband signal BB to output digital data. The modem chip 110 may include a processor executing instructions, and the processor may include at least one core. In addition, the modem chip 110 may be integrated with an application processor (AP) included in the communication device 100 as a single semiconductor chip.

The RF circuit 120 may perform conversion between a baseband signal BB and a carrier signal CS. For example, the carrier signal may be included in an RF band (e.g., may have a frequency bandwidth in the RF band). The RF circuit 120 may receive a baseband signal BB from the modem chip 110, and provide a carrier signal CS generated by processing the baseband signal BB to the antenna module 140. In addition, the RF circuit 120 may provide a baseband signal BB generated by processing the carrier signal CS received from the antenna module 140 to the modem chip 110.

The RF circuit 120 may include (e.g., be composed of) a one-stage circuit performing direct conversion between the baseband signal BB and the carrier signal CS. Alternatively, the RF circuit 120 may include (e.g., be composed of) a two-stage circuit including a first circuit of performing conversion between a baseband signal BB and an intermediate frequency (IF) signal and a second circuit of performing conversion between the IF signal and a carrier signal CS. The one-stage circuit and the two-stage circuit composed of the RF circuit 120 are merely examples, and the number of stages of the RF circuit 120 is not limited.

The antenna module 140 may include one or more antennas. The antenna module 140 may transfer a carrier signal CS received from a base station 201 to the RF circuit 120, or transmit a carrier signal CS from the RF circuit 120 to the base station 201.

The RF circuit 120 may generate a carrier signal CS based on a carrier band allocated by the network 200. For example, the RF circuit 120 may generate a carrier signal CS having a predetermined or alternatively, given bandwidth from a target center frequency. The RF circuit 120 may include a frequency mixer for converting the baseband signal BB into a carrier signal CS having the target center frequency. An LO signal output from a local oscillator (LO) (also referred to herein as an LO device) may be input to the mixer.

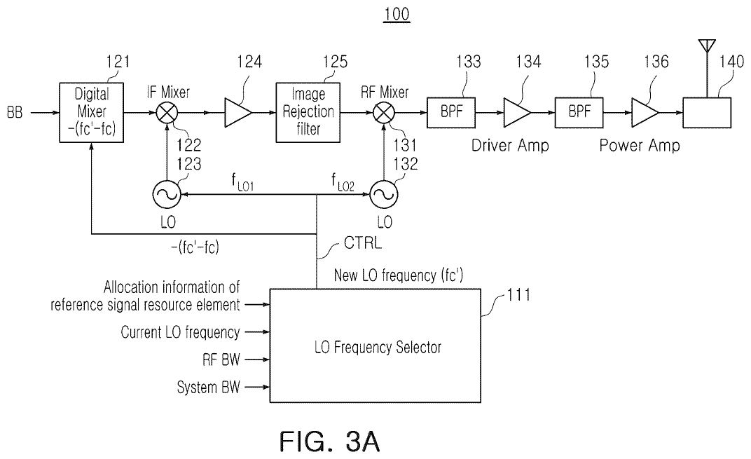

According to example embodiments of the inventive concepts, by adaptively adjusting the LO frequency, which is a frequency of the LO signal output from the LO device, the communication device 100 may improve the quality of the RF signal transmitted from the communication device 100, improve reception performance, and/or reduce power consumption. Hereinafter, referring to FIG. 2, an LO frequency will first be described by taking a case in which a baseband signal is upwardly converted into a carrier signal belonging to an RF band as an example.

FIG. 2 is a diagram illustrating an example in which a baseband signal is upwardly converted into a carrier signal.

A graph of FIG. 2 illustrates a baseband signal BB and a carrier signal CS of an RF band in a frequency domain. The baseband signal BB may have a determined bandwidth from a center frequency fb. The RF circuit 120 described with reference to FIG. 1 may generate a carrier signal holding information of the baseband signal and having the central frequency fc by shifting a center frequency fb of the baseband signal using the frequency mixer. The center frequency fc and bandwidth of the carrier signal may be determined by the network 200.

The center frequency fb of the baseband signal BB may be close to 0 Hz, and may be negligibly small compared to the center frequency fc of the carrier signal and a size of the carrier band. The LO frequency may be a value obtained by subtracting the center frequency fb from the center frequency fc, but the center frequency fb may be ignored.

An LO signal input to a mixer included in the RF circuit 120 may affect a carrier signal generated by the mixer. Due to characteristics of an LO device, an LO frequency may not be ideally fixed and may fluctuate. Furthermore, the LO signal may not have an ideal impulse waveform, and may have noise components due to the generation of flicker noise. The LO signal included in the carrier band may itself affect the carrier signal CS.

In addition, when the LO frequency and the baseband signal BB are mixed in the frequency mixer, unwanted signals such as an image frequency signal, spurious wave, and the like, may be generated as well as a carrier signal desired by the mixer. If the LO signal is included in the carrier band, these unwanted signals may adversely affect the generated carrier signal CS.

If the carrier signal CS is affected by the LO signal or these unwanted signals, it may be difficult for the base station to receive a reference signal included in the carrier signal CS and estimating a channel using the reference signal.

In order to reduce an adverse effect of the LO signal on the carrier signal, as illustrated in FIG. 2, a method of determining the LO frequency fc′ as a value out of the carrier band and compensating for the center frequency of the carrier signal using the separate mixer may also be considered. However, there are cases in which an RF band supported by the communication device 100 has an insufficient bandwidth to determine the LO frequency fc′ as a value out of the carrier band.

According to example embodiments of the inventive concepts, a method of improving transmission and reception performance of the communication device 100 by adaptively adjusting the LO frequency fc′ based on a bandwidth of the RF band, allocation information of the carrier signal CS, and the like, is proposed.

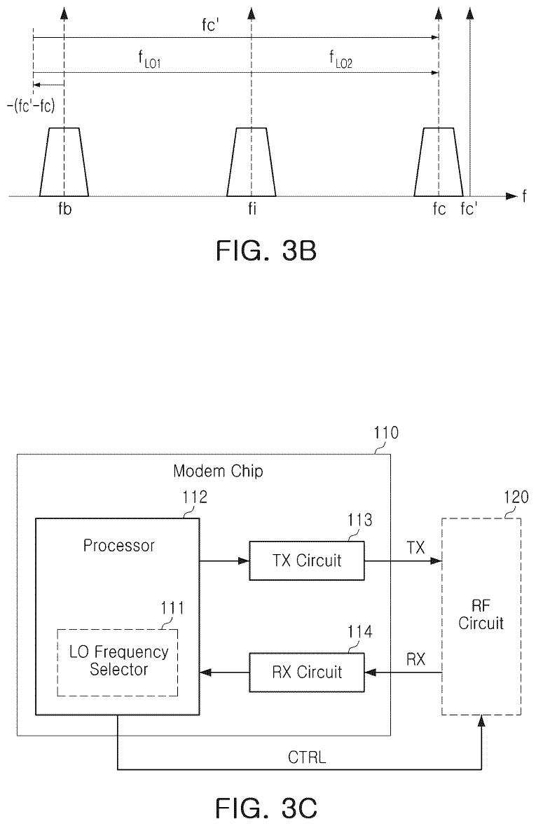

Hereinafter, a communication device 100 for converting a baseband signal BB into a carrier signal will be described in detail with reference to FIGS. 3A to 3C.

FIGS. 3A to 3C are diagrams for illustrating in detail a communication device according to example embodiments of the inventive concepts.

The communication device 100 of FIG. 3A may correspond to the communication device 100 described with reference to FIG. 1. Specifically, an LO frequency selector 111 of FIG. 3A may be driven by the modem chip 110 of FIG. 1. A digital mixer 121, an IF mixer 122, a first LO 123, a first amplifier 124, an image rejection filter 125, an RF mixer 131, a second LO 132, a first band pass filter 133, a second amplifier 134, a second band pass filter 135, and/or a third amplifier 136 of FIG. 3A may be included in the RF circuit 120 of FIG. 1. An antenna module 140 of FIG. 3A may correspond to the antenna module 140 of FIG. 1.

FIG. 3A illustrates a communication device 100 in which an RF circuit 120 converts a baseband signal BB into a carrier signal of an RF band through two-stage conversion. The digital mixer 121 may shift a center frequency of the baseband signal by −(fc′−fc). That is, the digital mixer 121 may be disposed at an input terminal of the IF mixer 122 to compensate for deviation between the target center frequency fc and the LO frequency fc′ in advance.

The IF mixer 122 may convert a baseband signal having a shifted center frequency into an IF band signal. A first LO frequency f_{LO1} generated from the first LO 123 may be input to the IF mixer 122 so that the IF mixer 122 converts the baseband signal into an IF band signal.

The first amplifier 124 may amplify the converted IF band signal. The image rejection filter 125 may output only a desired IF band signal by blocking an image frequency signal generated together with the IF band signal in the IF mixer 122.

The RF mixer 131 may convert an IF band signal output from the image rejection filter 125 into an RF band signal. A second LO frequency f_{LO2} generated from the second LO 132 may be input to the RF mixer 131 so that the RF mixer 131 converts the IF band signal into an RF band signal.

The RF band signal output from the RF mixer 131 may be amplified through a multi-stage amplifier. The multi-stage amplifier may include a second amplifier 134 referred to as a driving amplifier and a third amplifier 136 referred to as a power amplifier.

Among the RF band signals output from the RF mixer 131, a signal of a predetermined or alternatively, given band may pass through a first band pass filter 133, and a signal passing through the first band pass filter 133 may be amplified by the second amplifier 134. Among the RF band signals output from the second amplifier 134, a signal of a predetermined or alternatively, given band may pass through a second band pass filter 135, and a signal passing through the second band pass filter 135 may be amplified by the third amplifier 136. The RF band signal output from the third amplifier 136 may be externally output as a carrier signal through the antenna module 140.

According to example embodiments of the inventive concepts, by adaptively adjusting a value of the LO frequency fc′, an effect of the LO frequency fc′ on the carrier signal may be minimized (or reduced). For example, the LO frequency selector 111 may receive information such as allocation information of a reference signal resource element, a current LO frequency, an RF band (RFBW), a system band (System BW), and the like, and may adjust the LO frequency fc′ based on the received information.

As illustrated in FIG. 3A, when the baseband signal is converted into a carrier signal of the RF band through multi-stage mixers, an LO signal having an LO frequency fc′ obtained by mixing the first LO frequency f_{LO1} and the second LO frequency f_{LO2}. (e.g., the LO frequency fc′ may result from a combination of the first LO frequency f_{LO1} and the second LO frequency f_{LO2}).

For example, the LO frequency selector 111 may determine the LO frequency fc′, and determine a frequency (fc′−fc) of the digital mixer 121, the first LO frequency f_{LO1} and the second LO frequency f_{LO2}.

FIG. 3B illustrates an example of the LO frequency fc′, the center frequency fb, the central frequency fc, an intermediate frequency fi. The intermediate frequency fi may means a center frequency of the IF band signal output from the IF mixer 122.

The center frequency fb may be determined based on the baseband signal BB, and the center frequency fc and the intermediate frequency fi may predetermined. The first LO frequency f_{LO1} may be determined to be (fi+(fc′−fc)), and the second LO frequency f_{LO2} may be determined to be (fc−fi).

The LO frequency selector may provide the digital mixer 121, the first LO 123 and the second LO 132 with control signals CTRL each indicating value of (fc′−fc), (fi+(fc′−fc)) and (fc−fi). For example, the control signals CTRL may be digital signals. For example, the first LO 123 and the second LO 132 may be phased locked loop (PLL), and the first LO frequency f_{LO1} and the second LO frequency f_{LO2} may be controlled by the digital signals.

With reference to FIGS. 3A and 3B, a case where the RF circuit 120 converts the baseband signal BB into the IF band signal, and then converts the IF band signal into the RF band signal has been described as an example. However, the inventive concepts are not limited thereto. For example, when the RF circuit 120 performs direct conversion between the baseband signal BB and the carrier signal CS, an output signal of one LO may have a LO frequency fc′.

FIG. 3C illustrates a modem chip 110 in detail in which the frequency selector 111 is driven. The modem chip 110 may include a processor 112, a transmission circuit 113, and/or a reception circuit 114.

The processor 112 may process data signals exchanged with the network. The transmission circuit 113 may generate a baseband signal by modulating a data signal from the processor 112, and output the generated baseband signal to an RF circuit (e.g., the RF circuit 120). The reception circuit 114 may generate a data signal by demodulating a baseband signal received from the RF circuit, and provide the generated data signal to the processor 112. The transmission circuit 113 may include an encoder, a modulator, a resource mapper, a transmission filter, and the like, and the reception circuit 114 may include a decoder, a demodulator, a channel estimator, a reception filter, and the like.

The processor 112 may generate a reference signal to be transmitted to a network. A reference signal, for example, a demodulation reference signal (DMRS), may refer to a signal referenced by the communication device 100 for channel estimation in a base station 201 of the network 200. The base station 201 may estimate a reception channel of the communication device 100 using the reference signal transmitted from the communication device 100. The base station 201 may modulate a signal according to the estimated reception channel and transmit the modulated signal to the communication device 100. When the communication device 100 receives the modulated signal from the base station 201, the reception performance of the communication device 100 may be improved.

The processor 112 may obtain information on a carrier band and reference signal bands included in the carrier band by analyzing the data signal obtained from the reception circuit 114. The processor 112 may have currently set LO frequency and RF band information. The transmission circuit 113 may modulate the reference signal so that a frequency of the generated reference signal is included in one of the reference signal bands, and output the modulated reference signal to an RF circuit.

The processor 112 may control the communication device 100 as a whole. For example, the processor 112 may control an LO frequency fc′ by driving the frequency selector 111, and output a control signal CTRL for controlling the LO frequency fc′ to the RF circuit.

According to example embodiments of the inventive concepts, the processor 112 may adjust the LO frequency fc′ using the information. For example, the processor 112 may control the LO frequency fc′ to a value not overlapping the reference signal bands.

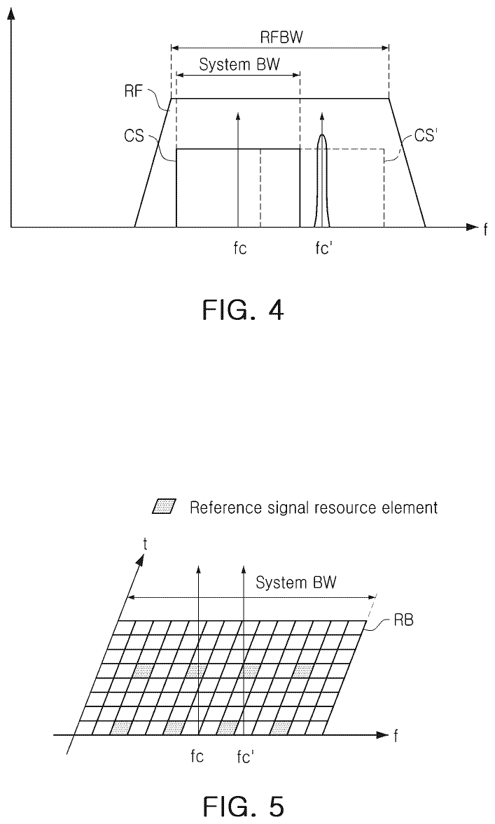

Hereinafter, a method of adjusting the LO frequency fc′ based on the above information will be described in detail with reference to FIGS. 4 to 9B.

FIG. 4 is a diagram illustrating a first example of adjusting an LO frequency.

Referring to FIG. 4, an RF band, a carrier band CS, and an LO frequency fc′ are illustrated in a frequency domain.

The RF band may refer to a band selected by the band pass filters 133 and 135 described with reference to FIG. 3A. The RF band may have an RF bandwidth (RFBW).

The carrier signal may have a determined system bandwidth (System BW) centered on a center frequency fc. The carrier signal CS may be determined by a base station 201 of the network 200. Specifically, the base station 201 may request the communication device 100 to set the system bandwidth (System BW) and the center frequency fc using higher layer signaling.

Designing the RF bandwidth (RFBW) in the communication device 100 may be important to selectively pass a desired signal. For example, the RF bandwidth (RFBW) may be set to include both a carrier band CS having the system bandwidth (System BW) and the center frequency fc, and a frequency band CS' having the system bandwidth (System BW) and the LO frequency fc′ as a center frequency.

The RF bandwidth (RFBW) may be determined not only by signal transmission characteristics but also by other parameters. For example, as the RF bandwidth (RFBW) widens, power consumption may increase, so the RF bandwidth (RFBW) may be set within a set power consumption limit.

If the RF bandwidth (RFBW) can be designed to be 1.5 times or more of the system bandwidth (System BW) within the power consumption limit, the LO frequency fc′ can be set to a value outside the carrier band CS, as shown in FIG. 4. On the other hand, when the RF bandwidth (RFBW) is designed to be less than 1.5 times of the system bandwidth (System BW), it may be difficult to design the LO frequency fc′ to have a value outside the carrier band CS.

According to example embodiments of the inventive concepts, when the RF bandwidth (RFBW) is limited to a threshold value or less, the communication device 100 may set the LO frequency fc′ to avoid (e.g., at least partially avoid) reference signal bands allocated for reference signal transmission.

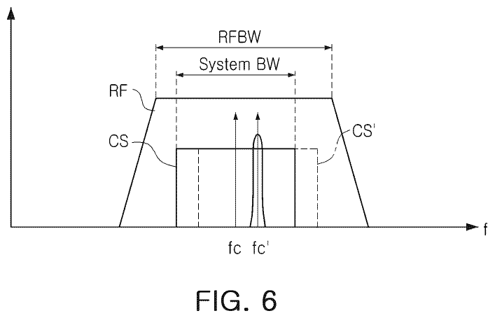

FIG. 5 is a diagram illustrating a resource block in a communication system communicating in an OFDM scheme.

In a communication system communicating using an orthogonal frequency division multiplexing (OFDM) method, when the network 200 allocates resources to the communication device 100, it may be allocated in units of resource blocks RB. A resource block may be allocated in a predetermined (or alternatively, given) time range and a predetermined (or alternatively, given) band. A band determined for allocating resource blocks may be defined by a center frequency fc and a system bandwidth (System BW).

The resource block may include a plurality of consecutive OFDM symbols in a time domain and a plurality of subcarriers in a frequency domain. For example, FIG. 5 illustrates a resource block RB comprising 8 OFDM symbols in the time domain and 14 subcarriers in the frequency domain. However, the number of OFDM symbols and the number of subcarriers is not limited thereto. For example, when the resource blocks RB has the same (or similar) system bandwidth (System BW), the number of subcarriers included in resource block RB may vary according to subcarrier spacing (SCS). For example, in a 5G NR network, the SCS may be variable to 15 kHz, 30 kHz, 60 kHz, 120 kHz, or 240 kHz, and the number of subcarriers may vary according to the variable SCS.

A resource element may refer to a minimum (or smallest) unit of resources that may be allocated by the network 200 in a resource block RB. For example, the resource element may correspond to one OFDM symbol and one subcarrier. In an example of FIG. 5, the resource block may include 8*14 resource elements.

The network 200 may allocate each of the resource elements included in the resource block RB to various types of signals. For example, certain resource elements may be allocated so that the communication device 100 may transmit a reference signal. In the example of FIG. 5, resource elements allocated to transmit a reference signal are exemplificd.

When the quality of the reference signal transmitted from the communication device 100 to the base station 201 is degraded, it may be difficult for the base station 201 to perform channel estimation using the reference signal. When it is difficult for the base station 201 to perform channel estimation, it may be difficult to properly modulate a signal transmitted to the communication device 100, and as a result thereof, the reception performance of the communication device 100 may deteriorate.

According to example embodiments of the inventive concepts, when determining the LO frequency fc′ within the band allocated to the resource block RB, the communication device 100 may determine the LO frequency fc′ to avoid (e.g., at least partially avoid) a band corresponding to resource elements allocated for the reference signal.

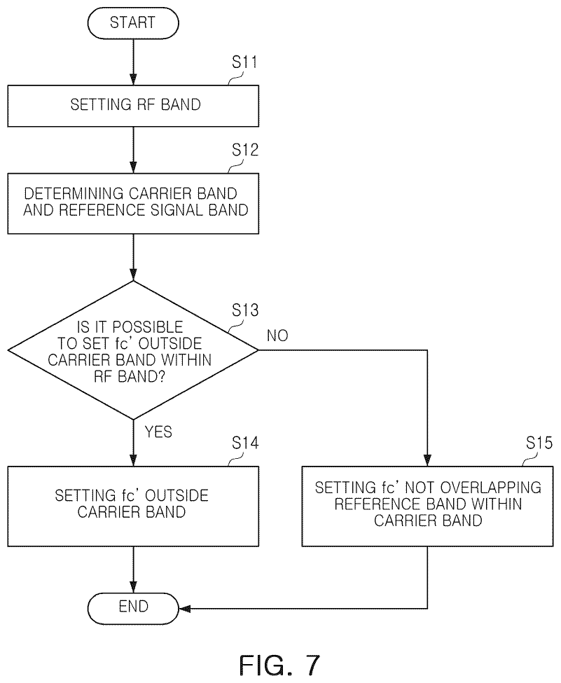

FIG. 6 is a diagram illustrating a second example of a relationship between an RF signal and an LO frequency.

Referring to FIG. 6, an RF band, a carrier band CS, and an LO frequency fc′ are illustrated in a frequency domain.

The RF band may have an RF bandwidth (RFBW). In an example of FIG. 6, band pass filters 133 and 135 may not provide a bandwidth enough for the LO frequency fc′ to be determined out of the carrier band CS.

In the example of FIG. 6, the LO frequency fc′ may be determined as a value capable of avoiding (e.g., at least partially avoiding) a band of resource elements allocated for a reference signal within a carrier band CS. In addition, the value of the LO frequency fc′ may be determined as a value such that a frequency band CS' having the same bandwidth as (or a similar bandwidth to) the system bandwidth (System BW) centered on the LO frequency fc′ does not deviate from the RF band.

According to example embodiments of the inventive concepts, the communication device 100 may minimize (or reduce) adverse effects due to the LO frequency fc′ on the reference signal to be transmitted to the network 200. Accordingly, reception performance of the communication device 100 may also be improved. In addition, since the RF bandwidth (RF BW) of the communication device 100 may be designed to be 1.5 times or less of the system bandwidth (System BW), power of the communication device 100 may be reduced.

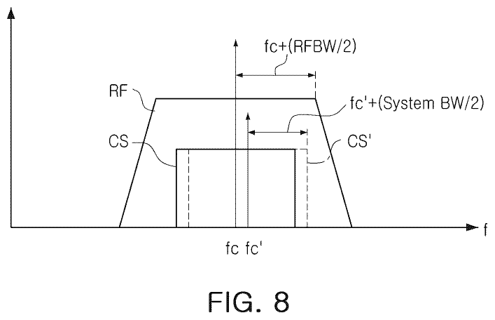

FIG. 7 is a diagram illustrating a method of setting an LO frequency according to example embodiments of the inventive concepts.

In operation S11, a communication device 100 may set an RF band of band pass filters 133 and 135.

In operation S12, the communication device 100 may determine a carrier band and a reference signal band. For example, the network 200 may allocate a carrier band to the communication device 100, and allocate a resource element for reference signal transmission in a resource block included in the carrier band. The network 200 may transmit allocation information to the communication device 100 through higher layer signaling. The communication device 100 may determine a carrier band based on the allocation information from the network 200, and may determine a reference signal band corresponding to the allocated resource element.

In operation S13, the frequency selector 111 of the communication device 100 may determine whether an LO frequency fc′ may be set outside the carrier band within the RF band. Specifically, it may be determined whether the LO frequency fc′ may be set outside a system band while a frequency band having the same bandwidth as (or a similar bandwidth to) the system bandwidth may be included in the RF band centered on the LO frequency fc′. According to example embodiments, in operation S13 the frequency selector 111 may determine whether an RF bandwidth of the RF band is less than or equal to a threshold value. The threshold value may be 1.5 times the system bandwidth, which is the RF bandwidth that the LO frequency can be set outside the carrier band.

When the LO frequency fc′ may be set outside the system band (“Yes” in operation S13), the frequency selector 111 may set the LO frequency fc′ outside the carrier band in operation S14. According to example embodiments, the frequency selector 111 may perform operation S14 in response to determining the RF bandwidth is less than or equal to the threshold value, which is the RF bandwidth that the LO frequency cannot be set outside the carrier band.

When the LO frequency fc′ may not be set outside the carrier band (“No” in operation S13), the frequency selector 111 may set an LO frequency fc′ not overlapping a reference signal band within the carrier band in operation S15. Even when the LO frequency fc′ is set within the carrier band, the LO frequency fc′ may be set so that conditions that the frequency band having the system bandwidth is included in an RF band are satisfied. According to example embodiments, the frequency selector 111 may perform operation S15 in response to determining the RF bandwidth exceeds the threshold value.

In the communication device 100, operations S11 to S15 may be repeatedly performed, and the LO frequency fc′ may be adaptively set according to changes in communication environments. For example, a carrier band or a reference signal band may be changed at the request of the network 200. When a current LO frequency overlaps the band of the changed reference signal, the communication device 100 may shift the current LO frequency to a new LO frequency.

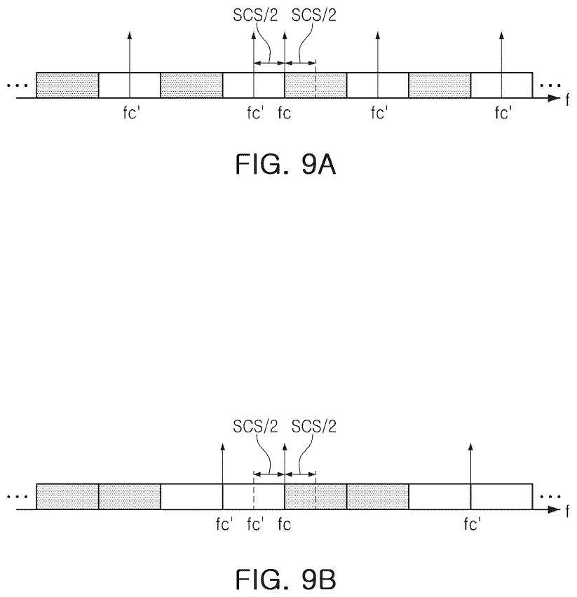

FIGS. 8 and 9B are diagrams specifically illustrating a method of setting an LO frequency according to example embodiments of the inventive concepts.

Like FIG. 6, FIG. 8 illustrates an RF band, a carrier band CS, and an LO frequency fc′ in a frequency domain.

In an example of FIG. 8, an RF band may be set to have a determined RF bandwidth (RFBW) centered on the center frequency fc. That is, the RF band may have a frequency range of fc−(RFBW/2) to fc+(RFBW/2).

The carrier band CS may be set to have a determined system bandwidth (System BW) centered on the center frequency fc. In addition, a frequency band CS' having a determined system bandwidth (System BW) centered on the LO frequency fc′ may be defined.

According to example embodiments of the inventive concepts, the LO frequency fc′ may be set to avoid (e.g., at least partially avoid) the reference signal band while belonging to the range defined by [Equation 1] below.

f′_{c}<f_{c}+(RFBW/2)−(System BW/2) [Equation 1]

In [Equation 1], fc′ may be an LO frequency, fc may be a target center frequency of the carrier signal, and RFBW may be the RF bandwidth, and System BW may be the system bandwidth.

FIGS. 9A and 9B illustrate a method of setting an LO frequency fc′ to avoid (e.g., at least partially avoid) a reference signal band according to example embodiments of the inventive concepts.

Referring to FIGS. 9A and 9B, a portion of subcarrier bands included in a carrier band are exemplified centered on a center frequency fc of the carrier band in a frequency domain. Subcarrier bands shaded in FIGS. 9A and 9B represent reference signal bands, and the remaining subcarrier bands represent normal subcarrier bands other than a reference signal band (e.g., subcarrier bands not allocated for transmitting a reference signal).

According to example embodiments of the inventive concepts, between reference signal bands, spaced apart from each other, an LO frequency fc′ may be set to a frequency farthest from the spaced reference signal bands. That is, the LO frequency fc′ may be set to an intermediate value of the frequency band in a frequency band between spaced reference signal bands.

In an example of FIG. 9A, the reference signal bands may be alternately allocated with the remaining subcarrier bands. According to example embodiments of the inventive concepts, the LO frequency fc′ may be determined to have a center frequency of the subcarrier band in any one of the normal subcarrier bands.

In the example of FIG. 9A, the LO frequency fc′ may be spaced apart from the center frequency fc of the carrier band by 0.5 times or more of the SCS. Setting the LO frequency fc′ to avoid (e.g., at least partially avoid) the reference signal band according to example embodiments of the inventive concepts may be distinguished from the deviation of the LO frequency fc′ from the center frequency fc due to characteristics of the LO element.

For example, due to the characteristics of the LO element, the value of the LO frequency fc′ may have a slight variation from the target frequency value. The natural variation of the LO frequency may be smaller than the SCS. That is, naturally, due to the characteristics of the LO element, the LO frequency fc′ may have a value that deviates from the center frequency fc within 0.5 times of SCS. The natural deviation of the LO frequency fc′ may be distinguished from setting the LO frequency fc′ according to example embodiments of the inventive concepts. According to example embodiments, the LO frequency fc′ may be set to one of a plurality of frequency values in the carrier band.

Spacing between a plurality of frequency values that may be set as the LO frequency fc′ within the carrier band (e.g., frequency values outside of the reference signal bands) may correspond to an integer multiple of SCS. In the example of FIG. 9A, the plurality of frequency values may have spacing corresponding to twice the SCS.

In an example of FIG. 9B, reference signal bands and normal subcarrier bands may be allocated so as to be adjacent to each other (e.g., contiguous across multiple subcarrier bands). In the example of FIG. 9B, the LO frequency fc′ may be determined to have an intermediate value of the frequency band in a frequency band between the reference signal bands, spaced apart from each other. The LO frequency fc′ may be spaced apart from the center frequency fc of the carrier band by at least one time the SCS. As in the example of FIG. 9A, setting the LO frequency fc′ to avoid (e.g., at least partially avoid) the reference signal band may be distinguished from the deviation of the LO frequency fc′ within 0.5 times of SCS at the center frequency fc due to the characteristics of the LO element.

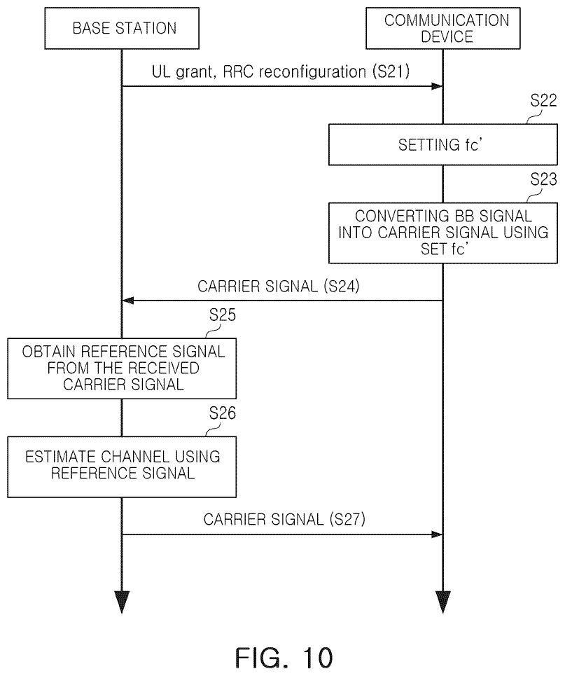

FIG. 10 is a diagram illustrating an operating method of a communication system according to example embodiments of the inventive concepts. Specifically, FIG. 10 illustrates an interaction between the communication device 100 and the base station 201 described with reference to FIG. 1.

In operation S21, the base station 201 may transmit resource allocation information to the communication device 100 through higher layer signaling. For example, the base station 201 may transmit a request defined in a communication protocol, such as an uplink (UL) grant signal or a radio resource control (RRC) reconfiguration signal, to the communication device 100.

In operation S22, the communication device 100 may set an LO frequency fc′ based on the resource allocation information received from the base station 201. According to example embodiments of the inventive concepts, the communication device 100 may set the LO frequency fc′ to a value capable of avoiding (e.g., at least partially avoiding) the reference signal band within the carrier band. The communication device 100 may minimize (or reduce) an adverse effect of the LO frequency fc′ on the carrier signal even when using a limited RF bandwidth. Example methods for setting the LO frequency fc′ by the communication device 100 have been described in detail with reference to FIGS. 4 to 9B.

In operation S23, the communication device 100 may convert a baseband signal BB into a carrier signal of the RF band by shifting a center frequency of baseband signal BB using the set LO frequency fc′. A method in which the communication device 100 converts the baseband signal BB into a carrier signal of the RF band using the LO frequency fc′ has been described in detail with reference to FIG. 3A.

In operation S24, the communication device 100 may transmit a carrier signal to the base station 201. The carrier signal may include a reference signal. According to example embodiments of the inventive concepts, the communication device 100 may transmit a higher-quality reference signal by setting the LO frequency fc′ to a value capable of avoiding (e.g., at least partially avoiding) the reference signal band within the carrier band. According to example embodiments, operation S23 may include generating the reference signal, and modulating the reference signal to have a frequency included in one of the reference signal bands.

In operation S25, the base station 201 may receive a carrier signal, and obtain a reference signal from the received carrier signal. In operation S26, the base station 201 may estimate a reception channel of the communication device 100 using the reference signal. According to example embodiments of the inventive concepts, since the base station 201 may obtain a higher-quality reference signal from the communication device 100, a channel state of the communication device 100 may be normally (e.g., successfully) estimated.

In operation S27, the base station 201 may transmit a modulated carrier signal to the communication device 100 based on the estimated channel state. According to example embodiments of the inventive concepts, since the communication device 100 may receive a modulated carrier signal based on the channel state, reception performance of the communication device 100 may be improved.

As set forth above, according to example embodiments of the inventive concepts, in a method of setting an LO frequency, a semiconductor device, and a communication device, by setting the LO frequency so that the LO frequency avoids (e.g., at least partially avoids) a reference signal band allocated by a network, an adverse effect of an LO signal on a carrier signal may be minimized (or reduced).

According to example embodiments of the inventive concepts, in a method of setting an LO frequency, a semiconductor device, and a communication device, by improving quality of a reference signal transmitted from the communication device, channel estimation performance of a network may be improved, and as a result, reception performance of the communication device may be improved.

Conventional devices and methods for generating a carrier signal upconvert a baseband frequency signal to a carrier frequency (e.g., radio frequency) signal by mixing the baseband frequency signal with a local oscillator signal of the carrier frequency. However, the local oscillator signal of the carrier frequency negatively effects the quality of the carrier signal due to their common frequency range. Accordingly, the conventional devices and methods experience a reduction in communication performance with respect to the carrier signal. For example, a base station attempting to receive a reference signal included in a carrier signal transmitted by the conventional devices experiences difficulty in estimating a channel using the reference signal due to the decreased quality of the carrier signal. As a result of this difficulty, the base station is unable to configure communications between the base station and the conventional devices with sufficient efficacy, causing decreased communication performance between the base station and conventional devices.

According to example embodiments, improved devices and methods are provided for generating a carrier signal. For example, the improved devices and methods may control a local oscillator to generate a local oscillator signal having a frequency outside of the carrier frequency band. In order to compensate for a difference between the frequency of the local oscillator signal and a target center frequency of the carrier signal, a center frequency of a baseband signal may be shifted. Accordingly, the improved devices and methods may overcome the deficiencies of the conventional devices and methods to at least prevent or reduce the negative effects on the quality of the carrier signal caused by a local oscillator signal in a same frequency range (or similar frequency range) as the carrier frequency, and thus, improve the communication performance of the improved devices and/or a corresponding base station.

Also, according to example embodiments, the improved devices and methods may control the local oscillator to generate a local oscillator signal having a frequency inside of the carrier frequency band. For example, the local oscillator signal may have a frequency outside of one or more reference signal bands while being inside the carrier frequency band. In so doing, the improved devices and methods are enabled to utilize less carrier frequency bandwidth (e.g., less RF bandwidth) and thus, reduce power consumption of the improved devices. Also, the improved devices are able to avoid or reduce the negative effects on the reference signals carried by the carrier signal caused by the local oscillator signal, and thus, improve the channel estimation of the base station and the communication performance of the improved devices and/or the corresponding base station.

According to example embodiments, operations described herein as being performed by the wireless communication system 10, the communication device 100, the network 200, the base station 201, the modem chip 110, the RF circuit 120, the LO frequency selector 111, the digital mixer 121, the IF mixer 122, the first LO 123, the first amplifier 124, the image rejection filter 125, the RF mixer 131, the second LO 132, the first band pass filter 133, the second amplifier 134, the second band pass filter 135, the third amplifier 136, the processor 112, the transmission circuit 113, and/or the reception circuit 114 may be performed by processing circuitry. The term ‘processing circuitry,’ as used in the present disclosure, may refer to, for example, hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The various operations of methods described above may be performed by any suitable device capable of performing the operations, such as the processing circuitry discussed above. For example, as discussed above, the operations of methods described above may be performed by various hardware and/or software implemented in some form of hardware (e.g., processor, ASIC, etc.).

The software may comprise an ordered listing of executable instructions for implementing logical functions, and may be embodied in any “processor-readable medium” for use by or in connection with an instruction execution system, apparatus, or device, such as a single or multiple-core processor or processor-containing system.

The blocks or operations of a method or algorithm and functions described in connection with example embodiments disclosed herein may be embodied directly in hardware, in a software module executed by a processor, or in a combination of the two. If implemented in software, the functions may be stored on or transmitted over as one or more instructions or code on a tangible, non-transitory computer-readable medium. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD ROM, or any other form of storage medium known in the art.

Example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail herein. Although discussed in a particular manner, a function or operation specified in a specific block may be performed differently from the flow specified in a flowchart, flow diagram, etc. For example, functions or operations illustrated as being performed serially in two consecutive blocks may actually be performed concurrently, simultaneously, contemporaneously, or in some cases be performed in reverse order.

As used herein the term “and/or” includes any and all combinations of one or more of the associated listed items. Although terms of “first” or “second” may be used to explain various components, the components are not limited to the terms. These terms should be used only to distinguish one component from another component. For example, a “first” component may be referred to as a “second” component, or similarly, and the “second” component may be referred to as the “first” component. Expressions such as “at least one of” when preceding a list of elements, modify the entire list of elements and do not modify the individual elements of the list. For example, the expression, “at least one of a, b, and c,” should be understood as including only a, only b, only c, both a and b, both a and c, both b and c, all of a, b, and c, or any variations of the aforementioned examples.

While example embodiments have been shown and described above, it will be apparent to those skilled in the art that modifications and variations could be made without departing from the scope of the inventive concepts as defined by the appended claims.

1. A semiconductor device comprising:
processing circuitry configured to,
determine a carrier band and reference signal bands based on a data signal received from a network, the carrier band and reference signal bands being allocated by the network, the reference signal bands corresponding to a reference signal for channel estimation, and the reference signal being within a carrier band, and
output a control signal causing a local oscillator (LO) to change a LO frequency to a value that does not overlap the reference signal bands.

2. The semiconductor device of claim 1, wherein the processing circuitry is configured to:
generate the reference signal, and
modulate the reference signal to have a frequency included in one of the reference signal bands, and
output the modulated reference signal.

3. The semiconductor device of claim 1, wherein
the reference signal bands are a portion of a plurality of subcarrier bands included in the carrier band; and
the processing circuitry outputs the control signal causing the LO to change the LO frequency such that the LO frequency is spaced apart from a center frequency of the carrier band by at least 0.5 times a subcarrier spacing (SCS).

4. The semiconductor device of claim 1, wherein the processing circuitry is configured to:
set a radio frequency (RF) band corresponding to a frequency band of an RF signal to be transmitted, and
control the LO frequency to have a first value within the carrier band in response to an RF bandwidth of the RF band being less than or equal to a threshold value.

5. The semiconductor device of claim 4, wherein the processing circuitry is configured to control the LO frequency to have a second value out of the carrier band in response to the RF bandwidth of the RF band exceeding the threshold value such that a first frequency band is included in the RF band, the first frequency band being centered on the LO frequency and having a same bandwidth as a system bandwidth of the carrier band.

6. A communication device comprising:
processing circuitry;
a radio frequency (RF) circuit configured to convert a baseband signal into a carrier signal, the carrier signal including a plurality of subcarrier signals; and
an antenna module configured to transmit the carrier signal to a network, wherein
the RF circuit is configured to,
generate a local oscillator (LO) signal having an LO frequency,
generate a first signal in which a difference between a target center frequency of the carrier signal and the LO frequency is compensated when the baseband signal is input, and
output the carrier signal having the target center frequency by mixing the first signal and the LO signal, and
the processing circuitry is configured to control the LO frequency to avoid reference signal bands among subcarrier bands included in a carrier band, the reference signal bands being allocated for transmitting a reference signal for channel estimation, and the carrier band being allocated by the network.

7. The communication device of claim 6, wherein the processing circuitry is configured to control the LO frequency such that the LO frequency is spaced apart from the target center frequency by at least 0.5 times a subcarrier spacing (SCS).

8. The communication device of claim 7, wherein the processing circuitry is configured to control the LO frequency to have one of a plurality of first frequency values, a spacing between the plurality of first frequency values corresponding to an integer multiple of the SCS.

9. The communication device of claim 6, wherein the processing circuitry is configured to determines an intermediate value of a first frequency band to be the LO frequency, the first frequency band being between two reference signal bands spaced apart from each other among the reference signal bands.

10. The communication device of claim 6, wherein the processing circuitry is configured to determine the target center frequency of the carrier signal, a system bandwidth of the carrier signal, and the reference signal bands based on allocation information received from the network.

11. The communication device of claim 6, wherein
the reference signal bands are previously allocated reference signal bands;
the LO frequency is a current LO frequency; and
the processing circuitry is configured to:
determine whether the current LO frequency overlaps new reference signal bands in response to determining the previously allocated reference signal bands have been changed by the network, and
determine a new LO frequency having a value that avoids the new reference signal bands.

12. The communication device of claim 6, wherein the RF circuit comprises:
a first LO;
a second LO;
a digital mixer configured to generate the first signal when the baseband signal is input;
an intermediate frequency (IF) mixer outputting an IF signal by mixing the first signal and a first output signal of the first LO; and
an RF mixer outputting the carrier signal by mixing the IF signal and a second output signal of the second LO,
wherein the LO signal corresponds to a signal obtained by mixing the first output signal and the second output signal.

13. The communication device of claim 12, wherein the RF circuit comprises:
an image filter configured to remove an image frequency from the IF signal.

14. The communication device of claim 12, wherein the RF circuit comprises:
a band pass filter having one or more stages, the band pass filter being configured to,
pass a signal included in an RF band, and
provide the passed signal to the antenna module.

15. The communication device of claim 14, wherein the processing circuitry is configured to determine the LO frequency to have a first frequency value such that a first frequency band is included in an RF band, the first frequency band being centered on the LO frequency and having a same bandwidth as a system bandwidth of the carrier signal.

16. A method of setting a local oscillator (LO) frequency of an LO signal, the LO signal being for converting a baseband signal into a carrier signal, the method comprising:
setting a radio frequency (RF) band of a band pass filter for passing the carrier signal;
determining a carrier band and a reference signal band, the reference signal band being allocated to a reference signal for channel estimation from among a plurality of subcarrier bands included in the carrier band; and
controlling the LO frequency to have a value that does not overlap the reference signal band in response to an RF bandwidth of the RF band being less than or equal to a threshold value, a difference between the LO frequency and a target center frequency of the carrier band being compensated.

17. The method of claim 16, wherein the controlling the LO frequency comprises determining the LO frequency such that a first frequency band is included in the RF band, the first frequency band being centered on the LO frequency and having a same bandwidth as a system bandwidth of the carrier band.

18. The method of claim 16, wherein the threshold value is equal to or greater than 1.5 times a system bandwidth of the carrier band.

19. The method of claim 18, further comprising:
controlling the LO frequency to have a value outside the carrier band in response to the RF bandwidth not exceeding the threshold value such that a first frequency band having a same bandwidth as the system bandwidth is included in the RF band.

20. The method of claim 16, wherein
the setting the RF band comprises setting a band having a determined RF bandwidth and centered on the target center frequency as the RF band; and
the controlling the LO frequency comprises determining the LO frequency based on the following [Equation 1]
f′_{c}<f_{c}+(RFBW/2)−(System BW/2), [Equation 1]
wherein fc′ is the LO frequency, fc is the target center frequency, RFBW is the RF bandwidth and System BW is a system bandwidth of the carrier band.

21. (canceled)
